(19) United States
(12) Patent Application Publication
(10) Pub. No.: US 2006/0163708 A1
(43) Pub. Date: Jul. 27, 2006

(54) Semiconductor device

(75) Inventor: Tomohiro Yoshida, Kawasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/319,135

(22) Filed: Dec. 28, 2005

(30) Foreign Application Priority Data
Jan. 25, 2005 (JP) 2005-017008

(51) Int. Cl. H01L 23/02

(52) U.S. Cl. 257/678

(57) ABSTRACT

A semiconductor device comprises: an envelope having a thermal conductivity; a semiconductor dies placed inside the envelope; and a sealing cap disposed so as to cover the envelope and having a thermal conductivity. The envelope is provided with a lead connection portion including a lead wire and a dies receiving portion which thermally conductively receives the semiconductor dies electrically connected to the lead wire, and the sealing cap includes a main body and a protruding portion which is contact with a surface of the semiconductor dies when the sealing cap is arranged so as to cover the dies receiving portion. A heat component generated from the semiconductor dies is radiated to the main body side of the sealing cap through the protruding portion.

### CROSS REFERENCE TO RELATED APPLICATION

This application is based upon and claims the benefit of priority from prior Japanese Patent Application No. 2005-17008 filed on Jan. 25, 2005, the entire contents of which are incorporated herein by reference.

### BACKGROUND OF THE INVENTION

1. Field of the Invention

The present invention relates to a semiconductor device, and more particularly, to a semiconductor device including a base substrate and semiconductor dies (pellets) mounted on a surface thereof.

2. Description of the Related Art

Heretofore, semiconductor devices, each of which includes semiconductor dies mounted on a base substrate and having highly integrated semiconductors, have been widely used as electronic components or parts.

In addition, concomitant with the development of higher power components, the size of this type highly integrated semiconductor dies is increased, and as a result, the size of a semiconductor device mounting the semiconductor dies also tends to be increased.

At the same time, as an amount of heat generated from the semiconductor dies is increased, improvement in heat radiation or dissipation properties thereof has also been attempted.

In related semiconductor dies, an amount of self-generation heat generated therefrom has been continuously increased concomitant with the trend toward development of higher power and more highly integrated semiconductor dies, and hence various measures have been taken to prevent breakage of semiconductor dies and/or degradation in properties thereof, which are caused by this heat generation.

As one of the measures mentioned above, a method has been used in which self-generation heat generated from a highly integrated semiconductor dies is cooled before it is heated to an abnormally high temperature. As a semiconductor device having this type of cooling measure, a device has been disclosed in Japanese Patent Laid-open (KOKAI) Publication No. HEI 5-129516.

A related semiconductor device will be described hereunder with reference to FIG. 4, that is a vertical cross-sectional view of a semiconductor device 1.

This semiconductor device 1 is composed of a base substrate 2, a relatively low heat-generating semiconductor dies 3 mounted in a recess 2a formed in this base substrate 2, bump electrodes 4 electrically conductively disposed on this semiconductor dies 3, a high power semiconductor dies 5 electrically conductively disposed on the bump electrodes 4, a sealing cap 6 which covers this semiconductor dies 5 so as to seal a space formed between the cap 6 and the base substrate 2, and heat radiation fins 7 thermally conductively disposed on the outer surface of this sealing cap 6.

The semiconductor dies 3 is primarily composed of a single crystal silicon semiconductor substrate and a memory circuit unit provided on one surface thereof, the memory circuit unit being formed of low power-consumption and single-functional active elements which generate a relatively small amount of heat. The bump electrodes 4 are each provided with external terminals 4a and 4b at two sides thereof so as to be electrically connected to the semiconductor dies 3 and 5. The semiconductor dies 5 is thermally conductively connected to the sealing cap 6 with a thermal conductive filler 8 provided therebetween. A peripheral portion of the sealing cap 6 is thermally conductively disposed on the base substrate 2 with a sealing agent 9 provide therebetween.

In the semiconductor device 1 having the structure as described above, in particular, heat generated from the high power semiconductor dies 5 generating relatively a large amount of heat can be positively radiated or dissipated from the radiation fins 7 via the sealing cap 6. Hence, abnormal increase in temperature caused by the heat generation from the semiconductor dies 5 can be avoided, and as a result, breakage of the semiconductor dies 5 and/or degradation in properties thereof can be prevented.

In the semiconductor device 1 of the structures mentioned above, the abnormal increase in temperature caused by the heat generated from the semiconductor dies 5 can be avoided. However, when a highly integrated semiconductor dies for high power application, such as a GaAs-FET, is used, there may cause a case that the amount of self-generation heat generated therefrom is considerably increased, and hence, the heat radiation capacity cannot sufficiently counteract this increase, and as a result, breakage of the semiconductor dies itself and/or degradation in properties thereof may arise in some cases.

### SUMMARY OF THE INVENTION

The present invention was conceived in consideration of the above circumstances and an object of the present invention is to provide a semiconductor device, in which even in a use of a semiconductor dies having a large amount of self-generation heat, the heat generated therefrom is efficiently absorbed, abnormal increase in temperature is prevented, and breakage of the semiconductor dies itself and/or degradation in properties thereof can be also prevented.

The above and other objects can be achieved according to the present invention by providing a semiconductor device comprising:

an envelope having a thermal conductivity;

a semiconductor dies placed inside the envelope; and

a sealing cap disposed so as to cover the envelope and having a thermal conductivity,

the envelope being provided with a lead connection portion including a lead wire and a dies receiving portion which thermally conductively receives the semiconductor dies electrically connected to the lead wire, and

the sealing cap including a main body and a protruding portion which is in thermally conductive contact with a surface of the semiconductor dies when the sealing cap is arranged so as to cover the dies receiving portion, wherein a heat component generated from the semiconductor dies is radiated to the main body side of the sealing cap through the protruding portion.

In a preferred embodiment of the above aspect of the present invention, the semiconductor device may further comprise a thermally conductive layer disposed on the surface of the semiconductor dies. The thermally conductive layer may be composed of a thermally conductive coating of polyimede.

The sealing cap may be formed with a heat radiation member, such as a plurality of heat radiation fins extending from the main body of the sealing cap.

The semiconductor device may further comprise a distributor/combiner disposed in the dies receiving portion, wherein heat generated from the semiconductor dies and heat generated from the distributor/combiner are radiated through the sealing cap.

In the semiconductor device of the present invention of the characters mentioned above, the heat generated from a semiconductor dies having a large amount of self-generation heat is efficiently absorbed, abnormal increase in temperature can be prevented, and breakage of the semiconductor dies and/or degradation in properties thereof does not occur.

The nature and further characteristic features of the present invention will be made more clear from the following descriptions made with reference to the accompanying drawings.

### BRIEF DESCRIPTION OF THE DRAWINGS

In the accompanying drawings:

FIG. 1 is a schematic front view of a heat radiation type semiconductor device according to the present invention;

FIG. 2 is a schematic vertical sectional view of a heat radiation type semiconductor device according to the present invention;

FIG. 3 is a cross-sectional view of the heat radiation type semiconductor device taken along a line III-III in FIG. 1; and

FIG. 4 is a cross-sectional view of an important portion of a semiconductor device having a conventional structure.

### DESCRIPTION OF THE PREFERRED EMBODIMENT

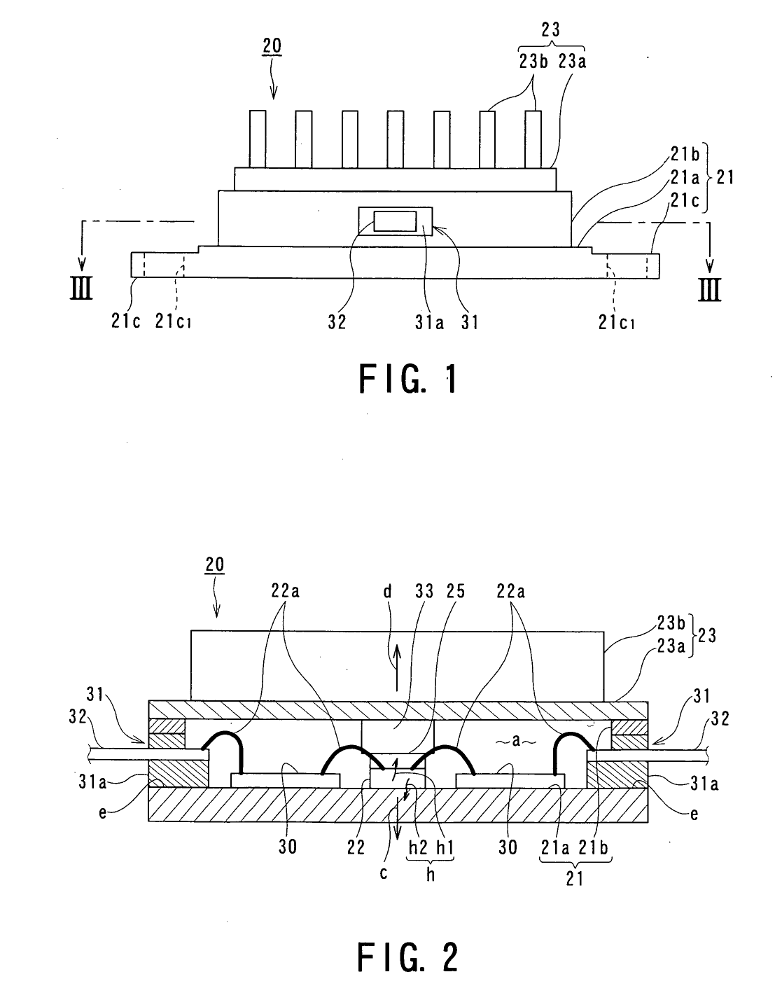

A semiconductor device according to one embodiment of the present invention will be described with reference to FIGS. 1 to 3.

This semiconductor device 20 is composed of an envelope 21 used as a base substrate, semiconductor dies (pellets) 22 mounted on this envelope 21 and used as a power element, and a sealing cap 23 covering the semiconductor dies 22 for sealing thereof.

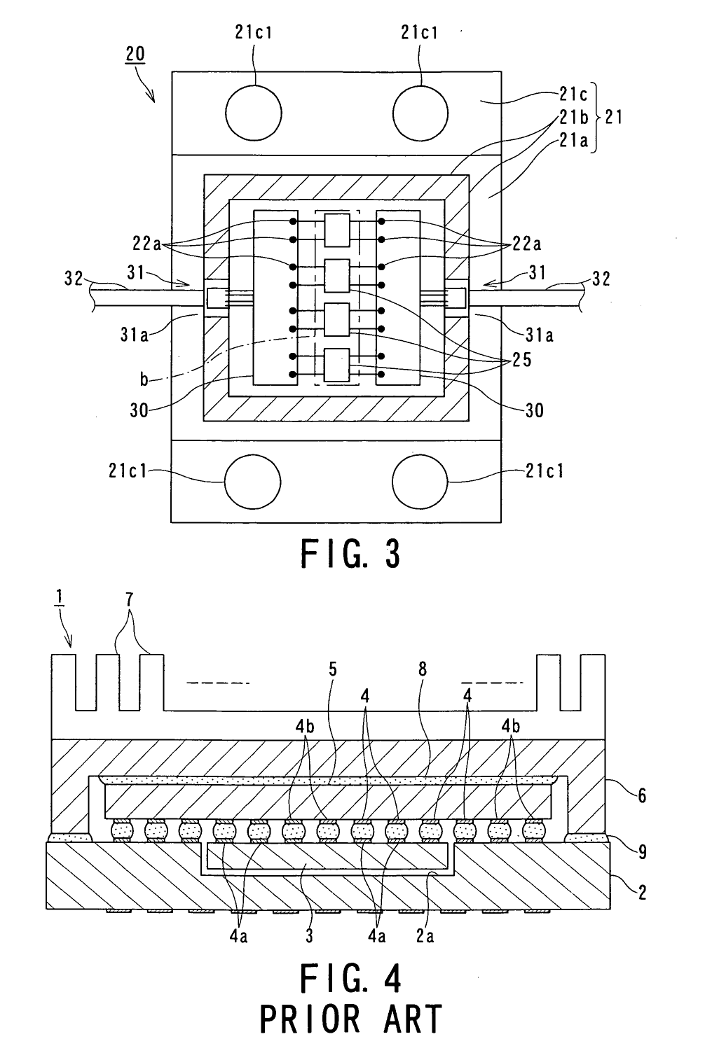

The envelope 21 is formed of a heat conductive material such as Cu—Mo and, as shown in FIGS. 2 and 3, is composed of a plate portion 21a, a wall portion 21b, and fitting portions 21c, the wall portion 21b being provided along the periphery of the plate portion 21a so as to form a dies receiving portion “a” thereon, the fitting portions 21c being integrally formed with the plate portion 21a so as to protrude outside from the two ends thereof. The fitting portions 21c are each provided with screw holes 21c1 for fixing and are fixed with screws to an apparatus, not shown, on which the semiconductor device 20 is to be mounted.

As the semiconductor dies 22, for example, a GaAs FET (Field Effect Transistor) is used which functions as a microwave power amplifier, and as shown in FIG. 3, at approximately the central portion of the upper surface of the plate portion 21a of the envelope 21, for example, four semiconductor dies 22 are linearly disposed. In addition, these semiconductor dies 22 are thermally conductively disposed on the plate portion 21a of the envelope 21 as shown in FIG. 2.

In each of the semiconductor dies 22 which are linearly disposed, fine metal wires 22a are provided at each of the two sides thereof used as electrical wires and are electrically connected to distributors/combiners (or distributing-combining elements) 30 used as elements disposed at both sides of the dies. These fine metal wires 22a are electrically fixed onto the semiconductor dies 22 and the distributor/combiner 30 under pressure.

The semiconductor dies 22 has a thermally conductive coating function as a thermally conductive film, such as a silicone gel layer 25, having a thickness of approximately several tens microns on the surface at the sealing cap side.

This silicone gel layer 25 has an intrinsic low dielectric constant and, hence, can reduce an adverse influence such as malfunction caused by dielectric effect on the circuit of the semiconductor dies 22. In addition, since the silicone gel layer 25 is formed to have a thickness of micrometer order, this silicone gel layer 25 has slight cushioning properties. Accordingly, when the sealing cap 23 is mounted so as to cover the dies receiving portion “a” of the envelope 21, a protruding portion 33 of the sealing cap 23 is elastically brought into contact with the surface of the semiconductor dies 22 with the silicone gel layer 25 provided therebetween, and hence, dimensional errors can be effectively absorbed.

In addition, in the wall portion 21b of the envelope 21 at positions facing the distributor or divider (combiners) 30 (i.e., distributor/combiner 30 which are electrical circuit making the electrical power dividing (distributing) or combining), lead wire connection portions 31 are provided. As shown in FIG. 2, for forming the lead connection portions 31, two parts of the wall portion 21b facing each other are partly cut away to form openings “e”, and in these openings “e”, insulating layers 31a are buried. In addition, lead wires 32 are provided to penetrate these insulating layers 31a thus buried and are electrically connected to the fine metal wires 22a each having the other terminal connected to the distributor/combiner 30.

The insulating layer 31a of the lead wire connection portion 31 is formed, for example, of an alloy-based insulating layer 31a, and the lead wire 32 penetrates the insulating layer 31a and is fixed thereby. The distributor/combiner 30 is electrically connected to the semiconductor dies 22 received in the dies receiving portion “a” of the envelope 21 and is each formed, for example, of a ceramic including a power distributing-combining circuit.

The sealing cap 23 has a plurality of heat radiation fins 23b as shown in FIG. 1 which externally radiates a self-generation heat component “h” of the semiconductor device 20, and a sealing cap main body 23a is soldered to the periphery of the envelope 21 to seal the dies receiving portion “a” thereof so as to achieve a desired sealing effect.

In this soldering, although the temperature in the dies receiving portion “a” is increased, for example, to approximately 200° C., the silicone gel layer 25 has superior heat stability, and hence the intrinsic properties thereof are not degraded.

In addition, the sealing cap 23 is formed by using a metal having a high thermal conductivity, such as copper, and has the protruding portion 33, the width thereof in the front view is slightly larger than the lateral width of the semiconductor dies 22 as shown in FIG. 2, the width thereof in the plan view is slightly larger than the total longitudinal width of all the semiconductor dies 22, and the shape thereof is rectangular protruding from the sealing cap main body 23a as shown in FIG. 3.

When the envelope 21 is covered with the sealing cap 23 for sealing, the protruding portion 33 is thermally conductively brought into contact with the semiconductor dies 22 provided in the dies receiving portion “a” with the silicone gel layers on the dies surfaces provided therebetween.

When the sealing cap 23 is provided on the envelope 21 for sealing as shown in FIG. 2, the protruding portion 33 of the sealing cap 23 is thermally conductively arranged to face the surfaces of the semiconductor dies 22 provided in the dies receiving portion “a” of the envelope 21 as shown by an imaginary line “b” in FIG. 3.

In addition, in a state in which the dies receiving portion “a” is sealed with the sealing cap 23, an inert insulating gas such as nitrogen is enclosed in the dies receiving portion “a” at a predetermined concentration. The generation of electrical short-circuiting and sparking caused by increase in temperature inside the dies receiving portion “a” can be prevented.

Next, the effect of the semiconductor device 20 will be described with reference to FIGS. 1 to 3.

When the semiconductor device 20 is operated, the self-generation heat component “h” of each semiconductor dies 22 is radiated into the environment. In the self-generation heat component “h”, a heat component “h1”, in a direction shown by an arrow “d” in FIG. 2 is thermally conducted to the protruding portion 33 of the sealing cap 23 through the silicone gel layer 25.

The heat component “h1” thermally conducted to the protruding portion 33 is thermally conducted to the sealing cap main body 23a and is further thermally conducted to the heat radiation fins 23b from the sealing cap main body 23a.

The heat component “h1” thermally conducted to the heat radiation fins 23b is dissipated outside through air cooling.

In addition, as shown in FIG. 2, in the self-generation heat component “h”, a heat component “h2” in a direction shown by an arrow “c” in FIG. 2 is thermally conducted to the plate portion 21a of the envelope 21. The heat component “h2” thermally conducted to the plate portion 21a is radiated outside through the plate portion 21a, the wall portion 21b, and the heat radiation fins 23b.

Hence, even if a relatively high capacity power element is used as the semiconductor dies 22, the semiconductor dies 22 is not heated to a predetermined temperature or more, thus preventing the semiconductor dies 22 from breaking and degrading in properties thereof.

In addition, in the dies receiving portion “a”, since abnormal increase in temperature does not occur, the silicone gel layer 25 normally functions while the properties thereof are not changed at all. That is, abnormal increase in dielectric constant and decrease in thermal conductivity do not occur, and in particular, thermal environment can be obtained in which the semiconductor dies 22 are normally operated in the dies receiving portion “a”. Accordingly, the semiconductor device 20 exhibits its stable functions in operation, and hence, the breakage of the semiconductor device 20 and/or the degradation in properties thereof can be avoided.

In addition, in the semiconductor device 20, when the sealing cap 23 is provided on the envelope 21 for sealing, the silicone gel layers 25 provided on the surfaces of the semiconductor dies 22 by coating are elastically brought into contact with the protruding portion 33 of the sealing cap 23, and hence the dimensional error can be absorbed. Accordingly, the semiconductor device 20 can be more efficiently assembled, that is, the semiconductor device 20 can be more efficiently manufactured.

In the semiconductor device 20, although a plurality of the semiconductor dies 22 provided in the dies receiving portion “a” of the envelope 21 and one protruding portion 33 are thermally conductively assembled together, in consideration of the amount of heat generated from each semiconductor dies 22 and heat resistance properties thereof, various types of protruding portions 33 having different amount of thermal conduction and/or thermal conductivities can also be provided.

With the structure described above, in which the protruding portion 33 of the sealing cap 23 is relatively large or has a high thermal conductivity, the amount of radiation heat can be increased. Hence, a semiconductor device having a reasonable size and lighter weight can be realized without unnecessarily increasing the size of the entire semiconductor device.

It is further to be noted that the present invention is not limited to the described embodiment and many other changes and modifications may be made without departing from the scopes of the appended claims.

What is claimed is:

1. A semiconductor device comprising:
an envelope having a thermal conductivity;
a semiconductor dies placed inside the envelope; and
a sealing cap disposed so as to cover the envelope and having a thermal conductivity,
said envelope being provided with a lead connection portion including a lead wire and a dies receiving portion which thermally conductively receives the semiconductor dies electrically connected to the lead wire, and
said sealing cap including a main body and a protruding portion which is in thermally conductive contact with a surface of the semiconductor dies when the sealing cap is arranged so as to cover the dies receiving portion, wherein a heat component generated from the semiconductor dies is radiated to the main body side of the sealing cap through the protruding portion.

2. The semiconductor device according to claim 1, further comprising a thermally conductive layer disposed on the surface of the semiconductor dies.

3. The semiconductor device according to claim 2, wherein said thermally conductive layer is composed of a thermally conductive coating of polyimede.

4. The semiconductor device according to claim 1, wherein said sealing cap is formed with a heat radiation member formed to the main body side thereof.

5. The semiconductor device according to claim 4, said hear radiation member is a plurality of heat radiation fins extending from the main body of the sealing cap.

6. The semiconductor device according to claim 1, further comprising a distributor/combiner disposed in the dies receiving portion, wherein heat generated from the semiconductor dies and heat generated from the distributor/combiner are radiated through the sealing cap.
